(19) United States
(12) Patent Application Publication
(10) Pub. No.: US 2022/0102304 A1
(43) Pub. Date: Mar. 31, 2022

(54) METHOD OF FORMING SEMICONDUCTOR STRUCTURE

(71) Applicant: NANYA TECHNOLOGY CORPORATION, New Taipei City (TW)

(72) Inventors: Ting-Cih KANG, New Taipei City (TW); Hsih-Yang CHIU, Taoyuan City (TW)

(21) Appl. No.: 17/643,419

(22) Filed: Dec. 9, 2021

Related U.S. Application Data
(62) Division of application No. 16/882,561, filed on May 25, 2020.

(51) Int. Cl. H01L 23/00

(52) U.S. Cl. CPC H01L 24/05; H01L 2224/02331; H01L 2224/05082; H01L 24/03

(57) ABSTRACT

A method of forming a semiconductor structure includes following steps. The first substrate is etched to form an opening, such that a first conductive pad of the first substrate is exposed through the opening. A first RDL pad is formed over the first conductive pad and extends to a top surface of the first substrate. A first bond pad is formed on a first portion of the first RDL pad, in which the first portion of the first RDL pad overlaps with the top surface of the first substrate.

### CROSS-REFERENCE TO RELATED APPLICATION

This application is a Divisional Application of the U.S. application Ser. No. 16/882,561, filed on May 25, 2020, the entirety of which is incorporated by reference herein in their entireties.

### BACKGROUND

### Technical Field

The present disclosure relates to a method of forming a semiconductor structure.

### Description of Related Art

With the rapid growth of electronic industry, the development of integrated circuits (ICs) has achieved high performance and miniaturization. Technological advances in IC materials and design have produced generations of ICs where each generation has smaller and more complex circuits than the previous generation. As the number of electronic devices on single chips rapidly increases, three-dimensional (3D) integrated circuit layouts, or stacked chip designs, have been utilized for certain semiconductor devices in an effort to overcome the feature size and density limitations associated with 2D layouts.

A testing process is performed on a conductive pad (also referred as a top metal) of a silicon wafer to monitor yield. However, the thickness of the conductive pad is generally decreased during the testing process and the following etching processes, thereby causing damage on the conductive pad. The damage on the conductive pad will cause the potential risk of the conductive pad broken and thus cause the decreased performance of the semiconductor devices.

### SUMMARY

One aspect of the present disclosure is a method of forming a semiconductor structure.

According to some embodiments of the present disclosure, a method of forming a semiconductor structure includes following steps. The first substrate is etched to form an opening, such that a first conductive pad of the first substrate is exposed through the opening. A first RDL pad is formed over the first conductive pad and extends to a top surface of the first substrate. A first bond pad is formed on a first portion of the first RDL pad, in which the first portion of the first RDL pad overlaps with the top surface of the first substrate.

In some embodiments, forming the first RDL pad is performed such that the first RDL pad has a flat top surface, and forming the first bond pad is performed such that the first bond pad is in contact with the flat top surface.

In some embodiments, the method of forming the structure further includes prior to forming the first RDL pad, forming a dielectric layer over the first substrate.

In some embodiments, the method of forming the structure further includes prior to forming the first bond pad, forming a dielectric layer over the first RDL pad.

In some embodiments, the method of forming the semiconductor structure further includes following steps. A second RDL pad is formed over a second substrate. A second bond pad is formed on the second RDL pad. The second bond pad is bonded to the first bond pad such that the second substrate is disposed over the first substrate.

In some embodiments, the method of forming the semiconductor structure further includes forming two dielectric layers respectively over the second substrate and the second RDL pad.

In some embodiments, bonding the second bond pad to the first bond pad is performed such that the first bond pad is aligned with the second bond pad.

In the aforementioned embodiments, since the first bond pad is disposed on the first portion of the first RDL pad overlapping with the top surface of the first substrate, the formation of the undesirable voids in the first bond pad can be inhibited, thereby improving the uniformity of the first bond pad. As a result, the performance of the semiconductor structure can be improved.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a cross-sectional view of a semiconductor structure in accordance with some embodiments of the present disclosure;

FIGS. 2, 3, 4, 5, 7, and 8 are cross-sectional views of a method of forming a semiconductor structure at various stages in accordance with some embodiments of the present disclosure; and

FIG. 6 is a layout view of the semiconductor structure at one stage of FIG. 5.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

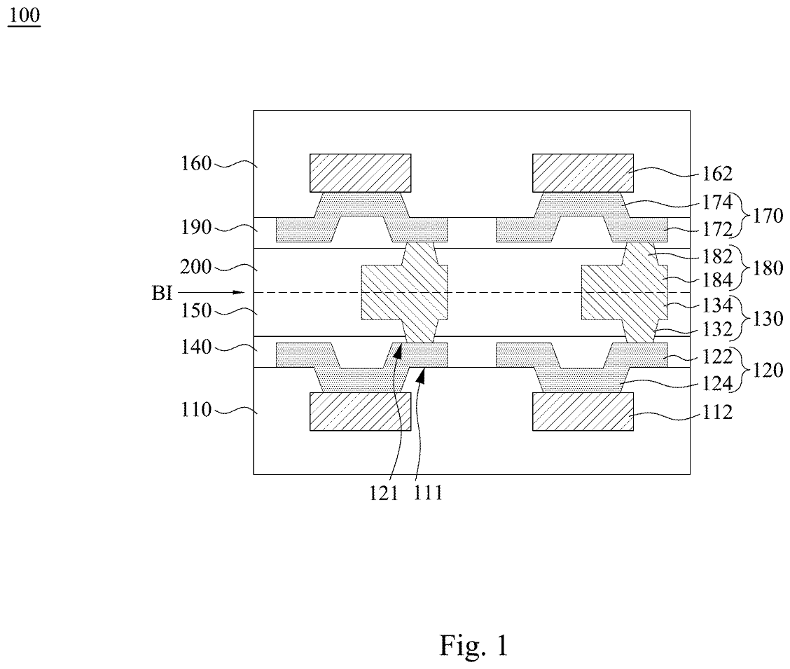

FIG. 1 is a cross-sectional view of a semiconductor structure 100 in accordance with some embodiments of the present disclosure. Referring to FIG. 1, the semiconductor structure 100 includes a first substrate 110, a first redistribution line (RDL) pad 120, and a first bond pad 130. The first substrate 110 has a first conductive pad 112. The first RDL pad 120 is disposed over the first conductive pad 112 and extends to a top surface 111 of the first substrate 110. The first bond pad 130 is disposed on a first portion 122 of the first RDL pad 120, and the first portion 122 of the first RDL pad 120 overlaps with the top surface 111 of the first substrate 110. The first portion 122 of the first RDL pad 120 may be referred as a landing pad for the first bond pad 130. As a result of such a configuration, the formation of the undesirable voids in the first bond pad 130 can be inhibited or avoided, thereby improving the uniformity of the first bond pad 130. As a result, the performance of the semiconductor structure 100 can be improved.

In some embodiments, the first substrate 110 may be a silicon wafer. Alternatively, the first substrate 110 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the first substrate 110 may include a dielectric layer therein, and the dielectric layer may be made of silicon oxide, silicon nitride, silicon oxynitride, or other suitable materials.

The first RDL pad 120 may further have a second portion 124 adjoining the first portion 122 and overlapping with the first conductive pad 112, and the first bond pad 130 is spaced apart from the second portion 124 of the first RDL pad 120. In other words, the first portion 122 of the first RDL pad 120 is disposed over the first substrate 110, and the second portion 124 of the first RDL pad 120 is disposed in the first substrate 110. The first bond pad 130 is in contact with the first portion 122 of the first RDL pad 120, while not in contact with the second portion 124 of the first RDL pad 120. In some embodiments, the first portion 122 of the first RDL pad 120 has a flat top surface 121, and the first bond pad 130 is in contact with the flat top surface 121. The flat top surface 121 of the first RDL pad 120 is substantially parallel to the top surface 111 of the first substrate 110. In some embodiments, the first RDL pad 120 may be made of copper (Cu), aluminum (Al), or other suitable conductive materials.

The first bond pad 130 may have a bottom portion 132 and a top portion 134 over the bottom portion 132, in which the bottom portion 132 is in contact with the first portion 122 of the first RDL pad 120. In some embodiments, a vertical projection region of the bottom portion 132 on the top surface 111 of the first substrate 110 is spaced apart from a vertical projection region of a central portion of the first conductive pad 112 on the top surface 111 of the first substrate 110. For example, the vertical projection region of the bottom portion 132 on the top surface 111 of the first substrate 110 partially overlaps with a vertical projection region of the first conductive pad 112 on the top surface 111 of the first substrate 110. In other embodiments, the vertical projection region of the bottom portion 132 on the top surface 111 of the first substrate 110 is spaced apart from the vertical projection region of the first conductive pad 112 on the top surface 111 of the first substrate 110. In some embodiments, the first bond pad 130 is a hybrid bond pad. The first bond pad 130 may be made of copper (Cu), or other suitable conductive materials.

In some embodiments, the semiconductor structure 100 further includes a dielectric layer 140 over the first substrate 110 and surrounding the first RDL pad 120. The dielectric layer 140 may be made of silicon oxide, silicon nitride, silicon oxynitride, or other suitable materials. In some embodiments, the semiconductor structure 100 further includes a dielectric layer 150 over the first RDL pad 120 and surrounding the first bond pad 130. The dielectric layer 150 may be made of silicon oxide, silicon nitride, silicon oxynitride, or other suitable materials. In some embodiments, the dielectric layer 140 surrounding the first RDL pad 120 and the dielectric layer 150 surrounding the first bond pad 130 may be made of same materials.

In some embodiments, the semiconductor structure 100 further includes a second substrate 160, a second RDL pad 170, and a second bond pad 180. The second substrate 160 is disposed over the first substrate 110, and the second substrate 160 has a second conductive pad 162. The second bond pad 180 is disposed over the first bond pad 130. The second RDL pad 170 is disposed between the second substrate 160 and the second bond pad 180. In addition, the second RDL pad 170 has a first portion 172 and a second portion 174 adjoining the first portion 172 and overlapping with the second conductive pad 162. The second bond pad 180 may have a top portion 182 and a bottom portion 184 below the top portion 182, and the top portion 182 is in contact with the first portion 172 of the second RDL pad 170.

In some embodiments, the semiconductor structure 100 further includes a dielectric layer 190 surrounding the second RDL pad 170, and a dielectric layer 200 surrounding the second bond pad 180. It is noted that the connection relationships and the materials of the second substrate 160, the second RDL pad 170, the second bond pad 180, the dielectric layer 190, and the dielectric layer 200 are respectively similar to those of the first substrate 110, the first RDL pad 120, the first bond pad 130, the dielectric layer 140, and the dielectric layer 150, and the description is not repeated hereinafter.

In some embodiments, the first bond pad 130 and the second bond pad 180 are disposed between the first RDL pad 120 and the second RDL pad 170. In other words, a combination of the first bond pad 130 and the second bond pad 180 extend from the first RDL pad 120 to the second RDL pad 170. The first bond pad 130 is aligned with the second bond pad 180, and the dielectric layer 150 surrounding the first bond pad 130 is in contact with the dielectric layer 200 surrounding the second bond pad 180.

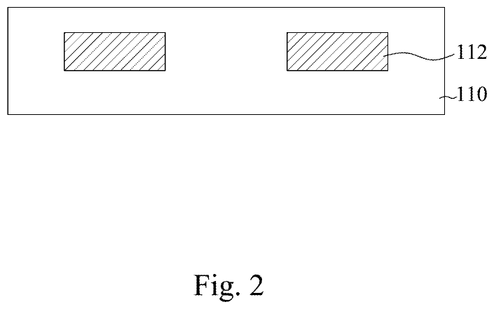

FIGS. 2, 3, 4, 5, 7, and 8 are cross-sectional views of a method of forming the semiconductor structure 100 of FIG. 1 at various stages in accordance with some embodiments of the present disclosure.

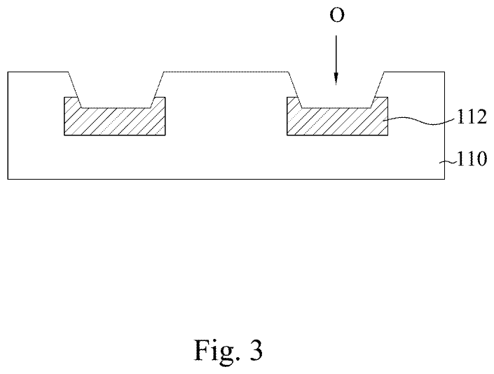

Referring to FIG. 2, the first conductive pad 112 is disposed in the first substrate 110. The first conductive pad 112 is made of metal, or other suitable conductive materials. Referring to FIG. 3, the first substrate 110 is etched to form an opening O, such that the first conductive pad 112 of the first substrate 110 is exposed through the opening O.

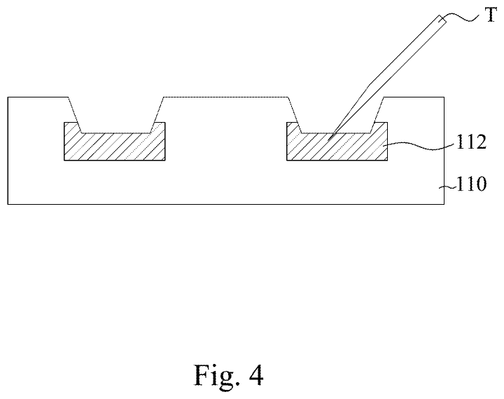

Referring to FIG. 4, a testing process is performed on the first conductive pad 112 of the first substrate 110. For example, a chip probing (CP) testing process is performed on the first conductive pad 112 of the first substrate 110 in order to monitor yield.

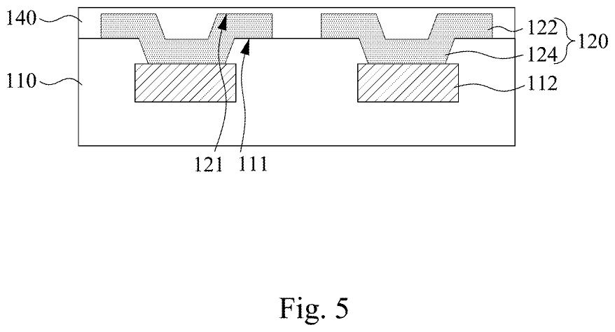

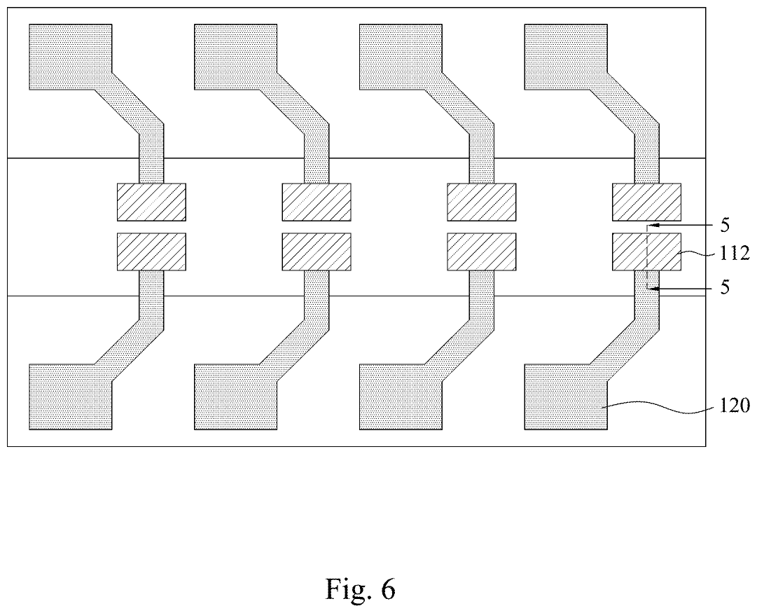

Referring to FIG. 5 and FIG. 6, FIG. 6 is a layout view of the semiconductor structure at one stage of FIG. 5. Stated differently, FIG. 5 is a cross-sectional view of the semiconductor structure taken along line 5-5 of FIG. 6. The dielectric layer 140 is formed over the first substrate 110. The dielectric layer 140 may be formed by chemical vapor deposition (CVD), atomic layer deposition (ALD), or other suitable methods.

Thereafter, the first RDL pad 120 is formed over the first conductive pad 112 and extends to the top surface 111 of the first substrate 110. For example, the method of forming the first RDL pad 120 may include etching the dielectric layer 140 to form an opening, and then filling conductive materials into the opening. In some embodiments, forming the first RDL pad 120 is performed such that the first RDL pad 120 has the flat top surface 121. For example, a planarization process, such as a CMP process, may be performed.

In some embodiments, the first RDL pad 120 may be made of copper (Cu), and prior to forming the first RDL pad 120, a barrier layer and a seed layer may be formed over the first conductive pad 112, in which the seed layer is conformally formed over the barrier layer and the first RDL pad 120 is formed over the seed layer. The barrier layer may be configured to prevent copper diffusion and may be made of tantalum (Ta), tantalum nitride (TaN), titanium nitride (TiN), or other suitable materials. The seed layer serves as an adhesive layer and includes a copper alloy. In other embodiments, the first RDL pad 120 may be made of aluminum (Al), and prior to forming the first RDL pad 120, an anti-reflective layer may be formed over the first conductive pad 112, in which the first RDL pad 120 is formed over the anti-reflective layer. The anti-reflective layer may be made of tantalum (Ta), tantalum nitride (TaN), titanium (Ti), titanium nitride (TiN), or other suitable materials.

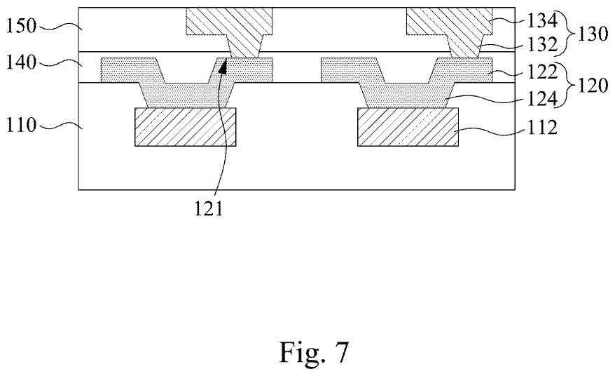

Referring to FIG. 7, after the first RDL pad 120 is formed, the dielectric layer 150 is formed over the first RDL pad 120. The dielectric layer 150 may be formed by chemical vapor deposition (CVD), atomic layer deposition (ALD), or other suitable methods.

Thereafter, the first bond pad 130 is formed on the first portion 122 of the first RDL pad 120, in which the first portion 122 of the first RDL pad 120 overlaps with the top surface 111 of the first substrate 110. For example, the method of forming the first bond pad 130 may include etching the dielectric layer 150 and a portion of the dielectric layer 140 to form an opening, and then filling conductive materials into the opening. The aforementioned opening may be formed by a damascene process. In some embodiments, the first bond pad 130 has a portion in the dielectric layer 140 and has the other portions in the dielectric layer 150. In some embodiments, forming the first bond pad 130 is performed such that the first bond pad 130 is in contact with the flat top surface 121 of the first RDL pad 120. Since the first bond pad 130 is formed on the flat top surface 121 of the first RDL pad 120, the formation of the undesirable voids in the first bond pad 130 can be inhibited or avoided, thereby improving the uniformity of the first bond pad 130. In addition, the first portion 122 of the first RDL pad 120 may be referred as a landing pad for the first bond pad 130 and the first portion 122 of the first RDL pad 120 is beneficial for the first bond pad 130 to bond on a flat metal (i.e., the first portion 122 of the first RDL pad 120). For example, the first bond pad 130 formed on the first portion 122 of the first RDL pad 120 instead of the first conductive pad 112 can prevent the potential risk of the first conductive pad 112 broken because an additional etching process may be performed on the first conductive pad 112 and may cause serious damage on the first conductive pad 112.

In some embodiments, the first bond pad 130 may be made of copper, and prior to forming the first bond pad 130, a barrier layer and a seed layer may be formed over the first RDL pad 120, in which the seed layer is conformally formed over the barrier layer and the first bond pad 130 is formed over the seed layer. The barrier layer may be configured to prevent copper diffusion and may be made of tantalum (Ta), tantalum nitride (TaN), titanium nitride (TiN), or other suitable materials. The seed layer serves as an adhesive layer and includes a copper alloy.

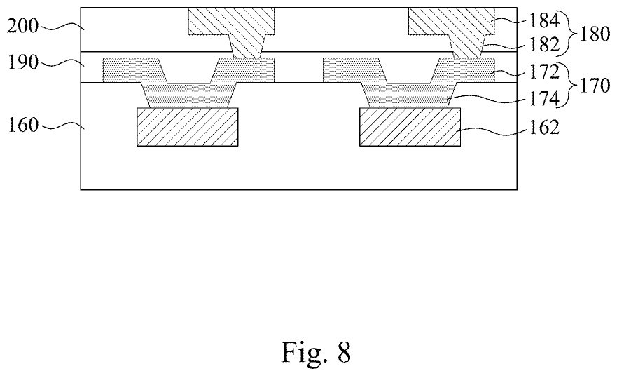

Referring to FIG. 7 and FIG. 8, the structure of FIG. 8 is similar to that of FIG. 7. The second RDL pad 170 is formed over the second substrate 160, and then the second bond pad 180 is formed on the second RDL pad 170. In some embodiments, the dielectric layer 190 is formed over the second substrate 160, and the dielectric layer 200 is formed over the second RDL pad 170. It is noted that the methods of forming the second RDL pad 170, the second bond pad 180, the dielectric layer 190, and the dielectric layer 200 are respectively similar to the methods of forming the first RDL pad 120, the first bond pad 130, the dielectric layer 140, and the dielectric layer 150, and the description is not repeated hereinafter.

Referring back to FIG. 1, the second bond pad 180 of FIG. 8 is then bonded to the first bond pad 130 such that the second substrate 160 is disposed over the first substrate 110. In some embodiments, bonding the second bond pad 180 to the first bond pad 130 may include a hybrid bonding process. The hybrid bonding process involves at least two types of bondings, including metal-to-metal bonding and non-metal-to-non-metal bonding. For example, the first bond pad 130 and the second bond pad 180 are bonded by metal-to-metal bonding, and the dielectric layer 150 and the dielectric layer 200 are bonded by non-metal-to-non-metal bonding. As shown in FIG. 1, the combination of the first bond pad 130 and the second bond pad 180 has a metallic bonding interface BI between the first bond pad 130 and the second bond pad 180 but may not have a clear non-metallic interface between the dielectric layer 150 and the dielectric layer 200 due to a reflowing process. In some embodiments, the first bond pad 130 is aligned with the second bond pad 180. As a result, the semiconductor structure 100 (3DIC stacking structure) shown in FIG. 1 can be obtained.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of forming a semiconductor structure, comprising:
etching a first substrate to form an opening, such that a first conductive pad of the first substrate is exposed through the opening;
forming a first RDL pad over the first conductive pad and extending to a top surface of the first substrate; and
forming a first bond pad on a first portion of the first RDL pad, wherein the first portion of the first RDL pad overlaps with the top surface of the first substrate.

2. The method of forming the semiconductor structure of claim 1, wherein forming the first RDL pad is performed such that the first RDL pad has a flat top surface, and wherein forming the first bond pad is performed such that the first bond pad is in contact with the flat top surface.

3. The method of forming the semiconductor structure of claim 1, further comprising:
prior to forming the first RDL pad, forming a dielectric layer over the first substrate.

4. The method of forming the semiconductor structure of claim 1, further comprising:
prior to forming the first bond pad, forming a dielectric layer over the first RDL pad.

5. The semiconductor structure of claim 1, further comprising:
forming a second RDL pad over a second substrate;
forming a second bond pad on the second RDL pad; and
bonding the second bond pad to the first bond pad such that the second substrate is disposed over the first substrate.

6. The semiconductor structure of claim 5, further comprising:
forming two dielectric layers respectively over the second substrate and the second RDL pad.

7. The semiconductor structure of claim 6, wherein bonding the second bond pad to the first bond pad is performed such that the first bond pad is aligned with the second bond pad.
